(19) United States
(12) Patent Application Publication
(10) Pub. No.: US 2002/0084494 A1
(43) Pub. Date: Jul. 4, 2002

(54) Method for making high gain bipolar transistors in CMOS process

(76) Inventors: Kamel Benaissa, Richardson, TX (US); Chi-Cheong Shen, Richardson, TX (US)

Correspondence Address: TEXAS INSTRUMENTS INCORPORATED, P O BOX 655474, M/S 3999, DALLAS, TX, 75265

(21) Appl. No.: 10/008,692

(22) Filed: Nov. 8, 2001

Related U.S. Application Data
(60) Provisional application No. 60/259,323, filed on Dec. 31, 2000.

(51) Int. Cl. H01L 29/76

(52) U.S. Cl. 257/370; 257/592

(57) ABSTRACT

Bipolar transistor performance is improved in CMOS process with deep wells by increasing the relative doping density between the emitter and base. To do this, the base dopant concentration is decreased in an npn device by using only the starting p substrate or epitaxial material, and NOT the p-well implant, to form the base*.

### BACKGROUND AND SUMMARY OF THE INVENTION

The present invention relates to integrated circuit structures and fabrication methods, and particularly to formation of bipolar transistors.

Background

Modern CMOS integrated circuit processes are normally optimized for features such as power consumption, performance of the NMOS and PMOS transistors, and cost, but NOT for fabrication of bipolar transistors. (Processes which are optimized for both MOS and bipolar transistor qualities are referred to as “BiCMOS” processes.) However, it has long been recognized that even a low-gain bipolar transistor can be very useful for some purposes, such as bandgap voltage references. Almost any bulk CMOS process permits a crude PNP transistor to be provided without process modifications, and many bulk CMOS processes provide a “free” NPN as well. However, the performance of such “free” bipolars is usually very low.

Improved Bipolar Transistor in a CMOS Process

The present application discloses an improvement to bipolar devices in a CMOS process. In the preferred embodiment for an npn device, instead of using the p well as the base, an epi layer (or just the p substrate material) is used as the base. This reduces the emitter:base doping concentration ratio, which increases the emitter efficiency. Other embodiments include using a blanket implant for the base. Another embodiment uses a base implant that is done at the same time as the deep well implantation. The innovative ideas are equally applicable to formation of pnp devices as well, with modifications in process context.

Advantages of the disclosed methods and structures, in various embodiments, can include one or more of the following:

transistor efficiency increased ten-fold over conventional designs;

no added mask steps for most embodiments;

allows formation of higher quality bipolar devices in a CMOS process.

### BRIEF DESCRIPTION OF THE DRAWINGS

The disclosed inventions will be described with reference to the accompanying drawings, which show important sample embodiments of the invention and which are incorporated in the specification hereof by reference, wherein:

FIG. 1 shows a conventional npn bipolar device.

FIG. 2 shows an innovative non device.

FIG. 3 shows an alternative embodiment of the innovative device.

### DETAILED DESCRIPTION OF THE PREFERRED EMBODIMENTS

The numerous innovative teachings of the present application will be described with particular reference to the presently preferred embodiment. However, it should be understood that this class of embodiments provides only a few examples of the many advantageous uses of the innovative teachings herein. In general, statements made in the specification of the present application do not necessarily delimit any of the various claimed inventions. Moreover, some statements may apply to some inventive features but not to others.

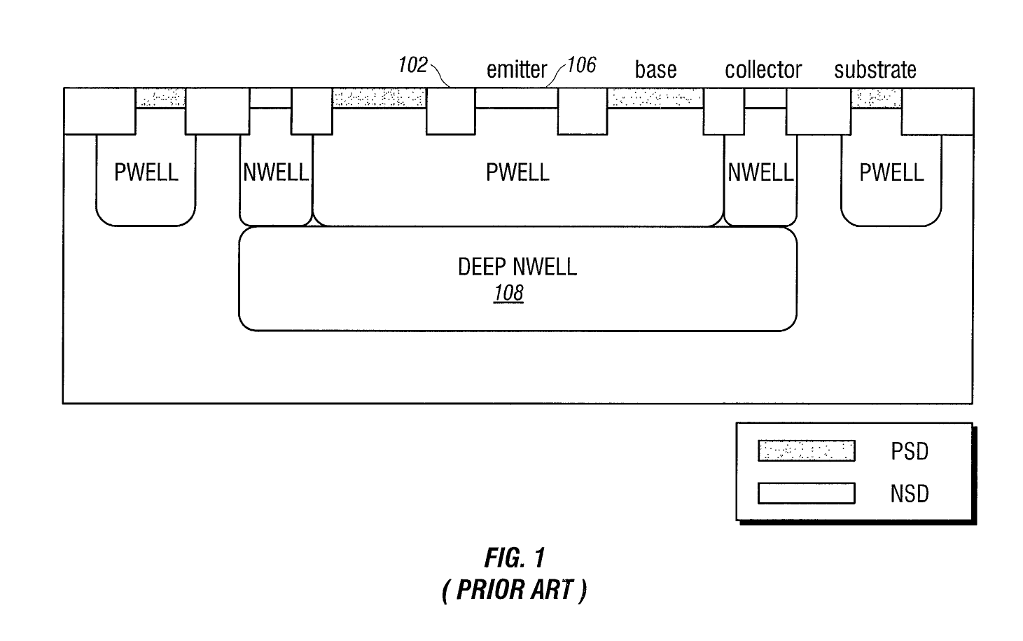

FIG. 1 shows a conventional design for an npn bipolar transistor in a CMOS process. Deep wells are used for the CMOS process field effect transistors and for isolation of the devices. Depending on the particular location, these are n wells or p wells, as shown. The CMOS devices are separated by shallow trench isolation 102. A p well 104 is located beneath the n source/drain 106 (and beneath the adjacent p source/drains) and is used as the base. The n source/drain serves as the emitter, with its high dopant concentration. Beneath the p well is the deep n well 108, which as a low resistance connection to the collector contact. Because of the doping concentration of the p well, the base has a relatively high carrier concentration compared to bulk silicon. This carrier concentration decreases the efficiency of the emitter.

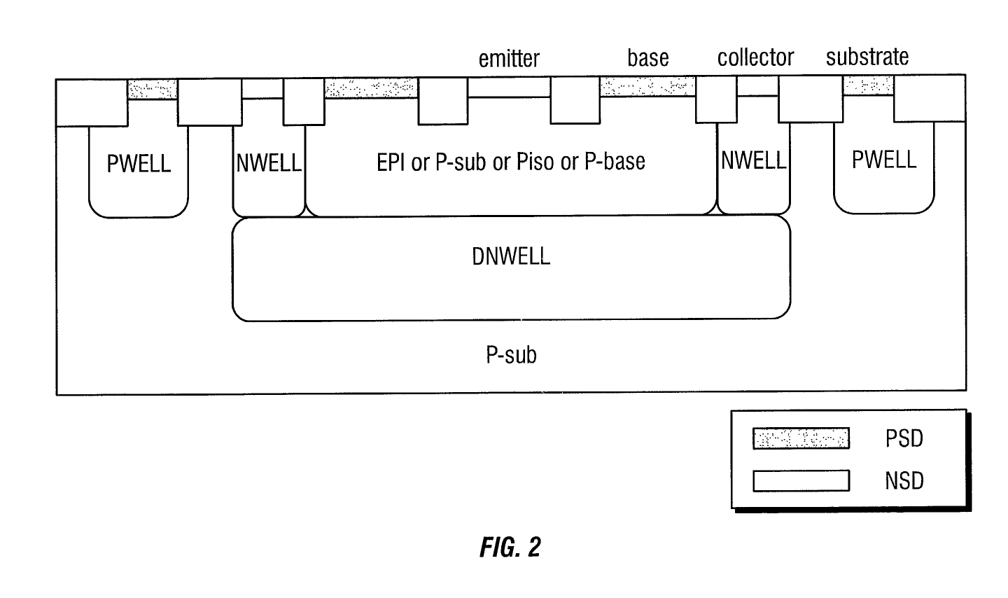

In order to increase the emitter carrier concentration relative to that of the base, the p well is replaced with monocrystalline silicon. Such an innovative design is shown in FIG. 2. Here, an npn device is shown in a p substrate CMOS context. Two n wells and a deep n well surround the epi layer, which is situated beneath the n source/drain. The n source/drain serves as the emitter. The epi layer, with its lower carrier concentration, serves as the base. Since the new base has a lower carrier concentration relative to the emitter in this design, the emitter efficiency is improved over the conventional design of FIG. 1. Again, the deep n well and the adjacent n wells serve as low contact connections for the collector of the npn device.

Any material with lower relative carrier concentration can be used as the base, though different approaches require different adjustments to surrounding device characteristics. For example, use of the epi layer as the base material requires in most CMOS contexts that the deep well be made deeper to avoid punch through of adjacent devices. Using the p substrate as the base material requires its own appropriate deep well to avoid punch through.

Other embodiments are also within the contemplation of the present application. For example, a low dose blanket implant can be used to form the base material, which may require the p well and n well implants to be adjusted to compensate. This blanket implant should be of adequate to create the base, but not to interfere with the well implants of the CMOS.

Another option within the present application is to use a p base implant to form the base. The p base implant can be done at the same time as the deep n well implant. This too may require adjustment of the p and n wells accordingly.

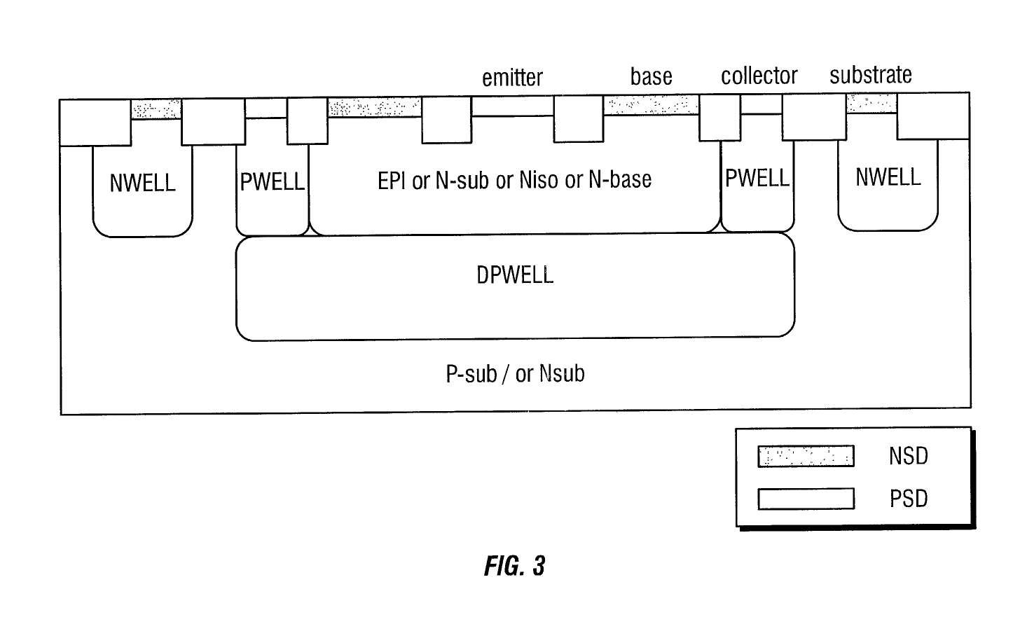

The innovative process is also applicable with pnp devices in CMOS processes with deep wells. Such a device is shown in FIG. 3. In this case, the emitter is formed from the p source/drain, and the deep p well serves as the collector (with the low resistance path to the collector contact through the p well). The base is formed from epi or the n substrate material, or from a blanket negative charge carrier implant or base implant, comparable to the npn device flow mentioned above.

The innovative process increases the gain of the bipolar device over conventional designs. For example, devices fabricated using the design of FIG. 1 typically demonstrate a gain of about 18. By increasing the relative emitter carrier concentration (by lowering the base carrier concentration), the gain for the innovative device is increased at least ten-fold. The device can be implemented in a CMOS context with deep well processes where little process effort is expended on forming bipolar devices. Since the innovative process requires no additional mask steps, superior bipolar transistors can be formed without increasing the necessary process efforts devoted to formation of bipolar devices.

Modifications and Variations

As will be recognized by those skilled in the art, the innovative concepts described in the present application can be modified and varied over a tremendous range of applications, and accordingly the scope of patented subject matter is not limited by any of the specific exemplary teachings given, but is only defined by the issued claims.

Similarly, it will be readily recognized that the described process steps can also be embedded into hybrid process flows, such as smart-power processes.

The teachings above are not necessarily strictly limited to silicon. In alternative embodiments, it is contemplated that these teachings can also be applied to structures and methods using other semiconductors, such as silicon/germanium and related alloys, gallium arsenide and related compounds and alloys, indium phosphide and related compounds, and other semiconductors, including layered heterogeneous structures.

It should also be noted that, over time, an increasing number of functions tend to be combined into a single chip. The disclosed inventions can still be advantageous even with different allocations of functions among chips, as long as the functional principles of operation described above are still observed.

Additional general background, which help to show the knowledge of those skilled in the art regarding variations and implementations of the disclosed inventions, may be found in the following documents, all of which are hereby incorporated by reference: Coburn, PLASMA ETCHING AND REACTIVE ION ETCHING (1982); HANDBOOK OF PLASMA PROCESSING TECHNOLOGY (ed. Rossnagel); PLASMA ETCHING (ed. Manos and Flamm 1989); PLASMA PROCESSING (ed. Dieleman et al. 1982); Schmitz, CVD OF TUNGSTEN AND TUNGSTEN SILICIDES FOR VLSI/ULSI APPLICATIONS (1992); METALLIZATION AND METAL-SEMICONDUCTOR INTERFACES (ed. Batra 1989); VLSI METALLIZATION: PHYSICS AND TECHNOLOGIES (ed. Shenai 1991); Murarka, METALLIZATION THEORY AND PRACTICE FOR VLSI AND ULSI (1993); HANDBOOK OF MULTILEVEL METALLIZATION FOR INTEGRATED CIRCUITS (ed. Wilson et al. 1993); Rao, MULTILEVEL INTERCONNECT TECHNOLOGY (1993); CHEMICAL VAPOR DEPOSITION (ed. M. L. Hitchman 1993); and the semiannual conference proceedings of the Electrochemical Society on plasma processing.

What is claimed is:

1. An integrated circuit comprising
NMOS transistors in P-wells,
PMOS transistors in N-wells, and
at least one NPN vertical bipolar transistor having a base diffusion which does not share the doping profile of said P-wells.
